(19) United States
(12) Patent Application Publication
(10) Pub. No.: US 2010/0092679 A1
(43) Pub. Date: Apr. 15, 2010

(54) Material layer forming apparatus using supercritical fluid, material layer forming system comprising the same and method of forming material layer

(75) Inventors: Jung-hyun Lee, Suwon-si (KR); Chang-soo Lee, Suwon-si (KR); Dong-joon Ma, Anyang-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/461,532

(22) Filed: Aug. 14, 2009

(30) Foreign Application Priority Data
Oct. 14, 2008 (KR) 10-2008-0100761

(51) Int. Cl. B05D 3/10; C23C 16/00; C23C 16/458

(52) U.S. Cl. 427/337; 118/715; 118/728

(57) ABSTRACT

Provided are a material layer forming apparatus using a supercritical fluid, a material layer forming system including the apparatus, and a method of forming a material layer using the system. The material layer forming system may include a high pressure pump supplying a supercritical fluid to a precursor storage container and the material layer forming apparatus, and maintaining the internal pressure of the precursor storage container, a reactant material storage container at a pressure such that the supercritical fluid is in a supercritical state, and a material layer forming apparatus. The material layer forming system may further include a pressure gauge adjusting the pressure of the material layer forming apparatus. The precursor of the precursor storage container may be supplied to the material layer forming apparatus using the supercritical fluid.

### CROSS-REFERENCE TO RELATED APPLICATIONS

This application claims priority under 35 USC §119 to Korean Patent Application No. 10-2008-0100761, filed on Oct. 14, 2008, in the Korean Intellectual Property Office (KIPO), the entire contents of which are incorporated herein by reference.

### BACKGROUND

1. Field

Example embodiments relate to a material layer forming apparatus and a method of forming the same, and more particularly, to a material layer forming apparatus using a supercritical fluid, a material layer forming system including the apparatus and a method of forming a material layer.

2. Description of the Related Art

As the integration degree of semiconductor devices is increased, structures of the semiconductor devices become smaller and more complicated. Accordingly, the semiconductor devices may include structures with relatively high aspect ratios. For example, a semiconductor device may include a capacitor of a DRAM having an aspect ratio of about 20:1 or higher or a shallow trench for cell separation of a flash memory having an aspect ratio of about 20:1 or higher.

However, completely supplying gas to the entire structure of a semiconductor device having a high aspect ratio may be difficult such as those mentioned above when using a deposition method of the related art using a gas flow method. Thus, regions having the high aspect ratio may not be completely filled or formed material layers may be non-uniform.

An atomic layer deposition (ALD) method may help to solve the above-described problems. However, the ALD method may be effective only in forming a material layer having a single component, and thus, the application may be limited.

### SUMMARY

Example embodiments include a material layer forming apparatus uniformly forming a material layer in a structure having a high aspect ratio, a material layer forming system including the material layer forming apparatus, and a method of forming a material layer using the material layer forming apparatus. Additional aspects will be set forth in part in the description which follows and, in part, will be apparent from the description, or may be learned by practice of example embodiments.

According to example embodiments, a material layer forming system may include a high pressure pump supplying a supercritical fluid to a precursor storage container, the precursor storage container supplying a precursor and the supercritical fluid to a material layer forming apparatus, and a reactant material storage container supplying a reactant material to the material layer forming apparatus, wherein the precursor and the reactant material react with each other in the material layer forming apparatus in order to form a material layer, and the internal pressure of the precursor storage container, the reactant material storage container, and the material layer forming apparatus is maintained higher than about 1 atm.

The material layer forming system may further include a pressure gauge adjusting the pressure of the material layer forming apparatus. The precursor of the precursor storage container may be supplied to the material layer forming apparatus using the supercritical fluid. The supercritical fluid may include CO₂, and the internal pressure of the precursor storage container, the reactant material storage container, and the material layer forming apparatus may be about 70 atm to about 200 atm.

The internal temperature of the precursor storage container, the reactant material storage container, and the material layer forming apparatus may be higher than about 400 K and lower than about 700 K. The material layer forming apparatus may further include a susceptor including a substrate loaded thereon, an upper board facing a surface of the susceptor including the substrate, the upper board being separate from the surface of the susceptor, an inlet on a side of the material layer forming apparatus between the susceptor and the upper board, wherein the supercritical fluid including the precursor and the reactant material flow into the material layer forming apparatus through the inlet, and an outlet on the other side of the material layer forming apparatus between the susceptor and the upper board, the outlet configured to discharge the supercritical fluid from the material layer forming apparatus.

According to example embodiments, a material layer forming apparatus may include a susceptor including a substrate loaded thereon, an upper board facing a surface of the susceptor including the substrate, the upper board being separate from the surface of the susceptor, an inlet on a side of the material layer forming apparatus between the susceptor and the upper board, wherein the supercritical fluid including the precursor and the reactant material flow into the material layer forming apparatus through the inlet, and an outlet on the other side of the material layer forming apparatus between the susceptor and the upper board, the outlet configured to discharge the supercritical fluid from the material layer forming apparatus, wherein the internal pressure of the material layer forming apparatus may be maintained to be higher than about 1 atm, and the supercritical fluid may be supplied between the substrate and the upper board through the inlet.

The inlet may include separate portions for supplying the reactant material and the supercritical fluid. The supercritical fluid may include CO₂, and the internal pressure of the material layer forming apparatus may be about 70 atm to about 200 atm. The internal temperature of the material layer forming apparatus may be higher than about 400 K and lower than about 700 K.

According to example embodiments, a method of forming a material layer may include loading a substrate on a susceptor, supplying a precursor to the substrate, and supplying a reactant material to the substrate, wherein the precursor may be melted in a supercritical fluid before being supplied to the substrate.

The reactant material may be melted in the supercritical fluid before being supplied to the substrate. The precursor and the reactant material may be supplied through different inlets. The material layer may be formed at a pressure higher than about 1 atm. The material layer may be formed at a temperature that is higher than about 400 K and lower than about 700 K.

The precursor and the reactant material may be supplied to the substrate at different times, and the method may further include supplying a pure supercritical fluid not containing the precursor and the reactant material to the substrate at a time between supplying the precursor and the reactant material. The pure supercritical fluid may be supplied after supplying the reactant material and before supplying the precursor. The precursor and the reactant material may be supplied in a parallel direction to the surface of the substrate where the material layer is formed. The precursor and the reactant material may be continually supplied until the material layer is completely formed. The material layer may be formed at a temperature that is higher than about 400 K and lower than about 700K.

### BRIEF DESCRIPTION OF THE DRAWINGS

These and/or other aspects will become apparent and more readily appreciated from the following description of example embodiments, taken in conjunction with the accompanying drawings of which:

FIG. 1 is a block diagram illustrating a material layer forming system according to example embodiments;

FIGS. 2 and 3 are respectively a cross-sectional view and a plan view illustrating a material layer forming apparatus of the material layer forming system of FIG. 1, according to example embodiments;

FIG. 4 is a graph showing a deposition rate of platinum according to pressure when a platinum layer is formed on an inner surface of a trench having a high aspect ratio using a supercritical fluid;

FIG. 5 is a graph showing a deposition rate of platinum according to temperature when a platinum layer is formed on an inner surface of a trench having a high aspect ratio using a supercritical fluid;

FIGS. 6 and 7 are cross-sectional views illustrating a material layer forming process using a supercritical fluid, according to example embodiments; and

FIG. 8 is a time chart in a material layer forming method using supercritical fluid.

### DETAILED DESCRIPTION

Reference will now be made in detail to example embodiments, examples of which are illustrated in the accompanying drawings, wherein like reference numerals refer to the like elements throughout. In the drawings, the thicknesses of layers and regions are exaggerated for clarity. In this regard, example embodiments may have different forms and should not be construed as being limited to the descriptions set forth herein.

It will be understood that, although the terms first, second, third etc. may be used herein to describe various elements, these elements should not be limited by these terms. These terms are used to distinguish one element from another. Thus, a first element discussed below could be termed a second element without departing from the teachings of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

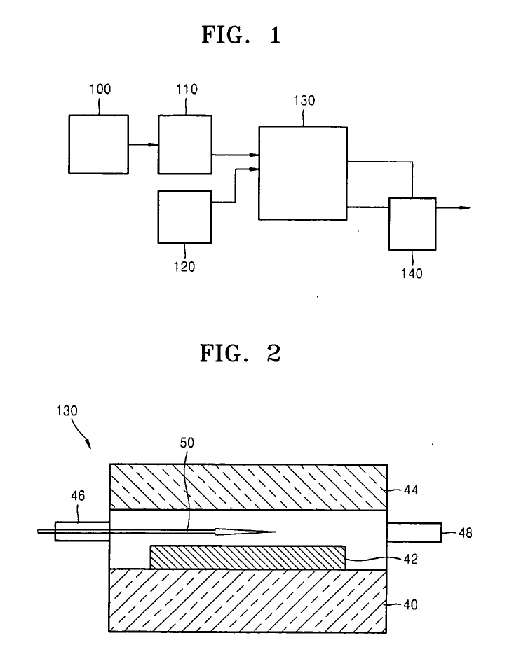

FIG. 1 is a block diagram illustrating a material layer forming system according to example embodiments. Referring to FIG. 1, the material layer forming system according to example embodiments may include a high pressure pump 100, a precursor storage container 110, a reactant material storage container 120, a material layer forming apparatus (reaction chamber) 130 in which a material layer is formed using a precursor and a reactant material that are received from the precursor storage container 110 and the reactant material storage container 120, respectively, and a back pressure gauge 140 maintaining the pressure of the material layer forming apparatus 130 through a feedback process.

A supercritical fluid may be supplied from the high pressure pump 100 to the precursor storage container 110 and the material layer forming apparatus 130. The supercritical fluid may be supplied to the material layer forming apparatus 130 via the precursor storage container 110. For example, the supercritical fluid may be CO₂. When the supercritical fluid is CO₂, the pressure of the supercritical fluid may be about 70 atm to about 250 atm. The temperature of the supercritical fluid may be about 25° C. to about 500° C.

A precursor containing a source material of a material layer to be formed on a substrate of the material layer forming apparatus 130 may be stored in the precursor storage container 110. If the material layer to be formed in the material layer forming apparatus 130 is a metal layer, an alloy layer, a conductive oxide layer, or an insulating layer (e.g., an oxide layer or a nitride layer), the source material may contain one or two metal components included in the metal layer, the alloy layer, the conductive oxide layer, or the insulating layer, and the precursor may further include a component for oxidizing or nitrifying the metal components.

The precursor storage container 110 may store the precursor before a supercritical fluid is supplied from the high pressure pump 100. However, when a supercritical fluid is supplied from the high pressure pump 100 to the precursor storage container 110, the precursor may be supplied from a separate precursor supply source to the precursor storage container 110. In example embodiments, the precursor storage container 110 may be simply a mixing container in which the supercritical fluid and the precursor are mixed.

The precursor stored in the precursor storage container 110 may be melted in the supercritical fluid which is supplied from the high pressure pump 100. The amount of the precursor melted in the supercritical fluid may be adjusted. The supercritical fluid including the precursor may be supplied to the material layer forming apparatus 130. A reactant material for dissolving the precursor deposited on the substrate may be supplied from the reactant material storage container 120 to the material layer forming apparatus 130. The pressure of the precursor storage container 110, the reactant material storage container 120, and the material layer forming apparatus 130 may be maintained at a pressure such that the supercritical fluid is continually in a supercritical state. The pressure may be higher than about 1 atm.

Accordingly, the pressure of the reactant material supplied from the reactant material storage container 120 to the material layer forming apparatus 130 becomes identical to the pressure of the supercritical fluid. The reactant material and the supercritical fluid may be supplied to the material layer forming apparatus 130 at the same time. The back pressure gauge 140 measures the pressure of the material layer forming apparatus 130, and maintains the internal pressure of the material layer forming apparatus 130 at a pressure at which the supercritical fluid supplied to the material layer forming apparatus 130 is maintained in a supercritical state. Accordingly, when the internal pressure of the material layer forming apparatus 130 is higher than a pressure that is needed to maintain the supercritical fluid in the supercritical state, the supercritical fluid supplied to the material layer forming apparatus 130 may be discharged through a discharging unit up to a certain degree.

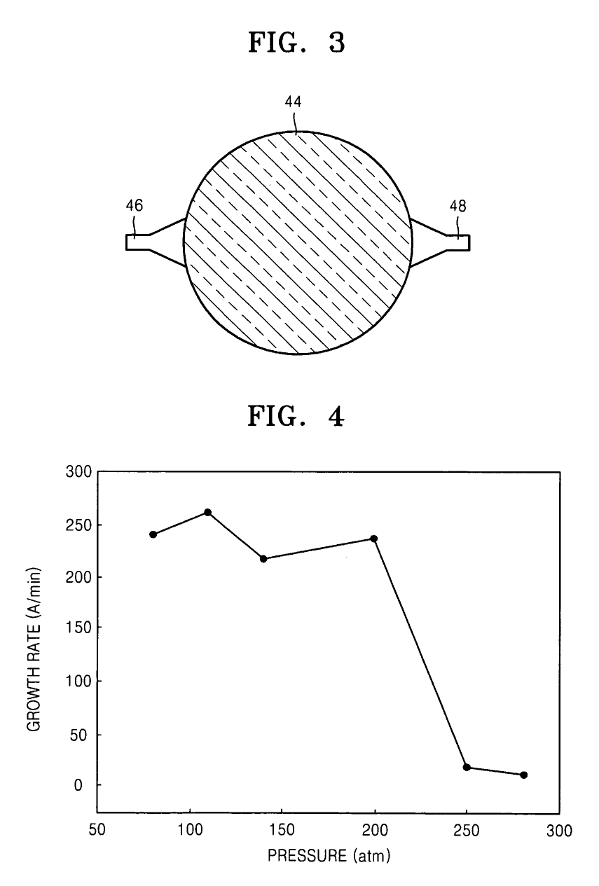

FIGS. 2 and 3 are respectively a cross-sectional view and a plan view illustrating the material layer forming apparatus 130 of FIG. 1, according to example embodiments. Referring to FIG. 2, the material layer forming apparatus 130 may include a susceptor 40 on which a substrate 42 is mounted, and an upper board 44. The susceptor 40 and the upper board 44 may face each other and may be separated from each other by a predetermined or given interval. For example, the upper board 44 may be separated from an opposite surface of the substrate 42 by about 3 mm to about 9 mm. An inlet 46 may be formed at a side of the material layer forming apparatus 130, between the susceptor 40 and the upper board 44. An outlet 48 may be formed on the opposite side of the material layer forming apparatus 130, directly opposite the inlet 46. However, the position of the outlet 48 is not limited to being directly opposite to the inlet 46.

In this regard, the inlet 46 may be formed at any position between the substrate 42 and the upper board 44. The inlet 46 may penetrate the side. A supercritical fluid, in which a precursor is melted, may flow from the precursor storage container 110 into the material layer forming apparatus 130 through the inlet 46. At the same time, a reactant material may flow from the reactant material storage container 120 into the material layer forming apparatus 130. Although not illustrated in the drawing, the inlet 46 may include an inlet through which the supercritical fluid containing the melted precursor flows, and an inlet through which the reactant material flows. However, the inlet 46 may be a single passage. Accordingly, the supercritical fluid, in which the precursor is melted, and the reactant material may be mixed in the inlet 46 and flow through the inlet 46. Reference numeral 50 refers to the supercritical fluid, in which the precursor is melted, and the reactant material that flow through the inlet 46.

As shown in FIG. 2, the precursor and the reactant material may be supplied in a parallel direction to the surface of the substrate on which a material layer is to be formed. A plurality of the inlets 46 may be disposed on the side of the material layer forming apparatus 130 between the susceptor 40 and the upper board 44. The plurality of the inlets 46 may be arranged along the side symmetrically. Also, a plurality of the outlets 48 may be arranged at the side of the material layer forming apparatus 130 at which the outlet 48 is disposed.

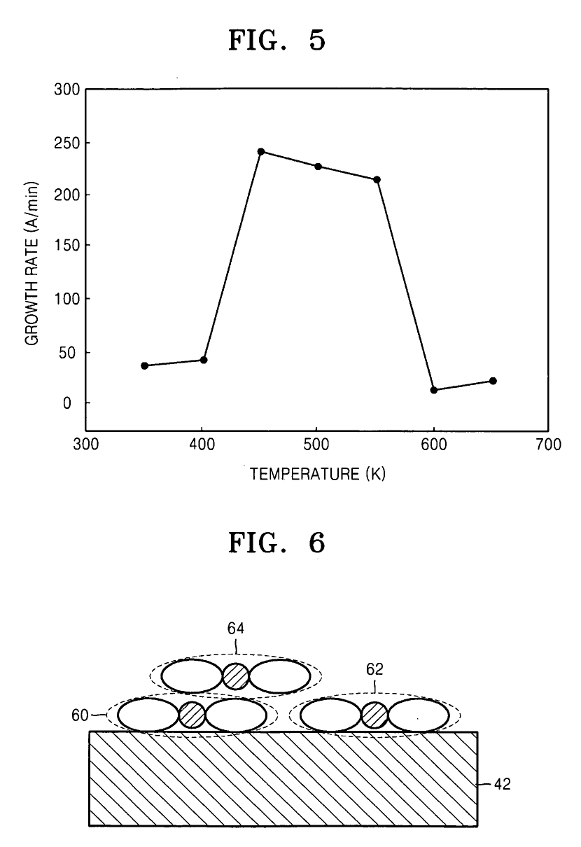

FIGS. 4 and 5 are graphs showing the characteristics of the material deposition according to pressure and temperature when forming a material layer by supplying the supercritical fluid, in which the precursor is melted, and the reactant material to the material layer forming apparatus 130.

In detail, FIG. 4 is a graph showing the deposition rate of platinum according to pressure when a platinum layer is formed on an inner surface of a trench having a high aspect ratio using a supercritical fluid. FIG. 5 is a graph showing the deposition rate of platinum according to temperature when a platinum layer is formed on an inner surface of a trench having a relatively high aspect ratio using a supercritical fluid.

Referring to FIG. 4, when a platinum layer is formed using a supercritical fluid in which a platinum precursor is melted, the platinum layer may be formed at a pressure, e.g., about 70 atm to about 200 atm, and at a temperature at which a supercritical state is maintained. In addition, the deposition rate of the platinum may be substantially uniform at a pressure, e.g., about 70 atm to about 200 atm. That is, when using the supercritical fluid, the deposition rate of the platinum may not be affected in a pressure of about 70 atm to about 200 atm.

Referring to FIG. 5, when a platinum layer is formed using a supercritical fluid in which a platinum precursor is melted, platinum may be deposited at a temperature higher than about 400 K and lower than about 700 K and at a pressure at which a supercritical state is maintained. Also, the deposition rate of the platinum layer at a temperature of about 450 K to about 560 K is uniform. That is, the deposition rate of the platinum may not be affected at a temperature of about 450 K to about 560 K when the supercritical fluid is used.

The characteristics shown in FIGS. 4 and 5 are not due to the material to be deposited but due to the supercritical fluid, and thus, the characteristics shown in FIGS. 4 and 5 may also be applied to formation of other material layers besides a platinum layer.

As described above, when forming a material layer using the material layer forming apparatus 130 using a supercritical fluid according to example embodiments, the deposition rate of the material at the temperature and pressure at which the supercritical fluid state is maintained is uniform, and thus, the material layer may be formed with a relatively uniform thickness. Also, because the supercritical fluid has both gaseous and liquid properties, the penetration and diffusion into complicated fine structures will be improved, and may have improved dissolving properties compared with gas, and thus, a uniform material layer may be formed in an entire structure having a high aspect ratio.

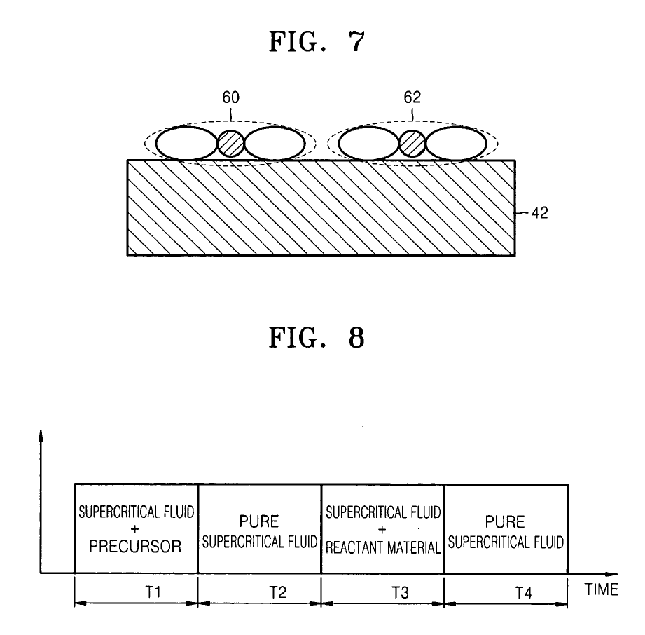

Hereinafter, a method of forming a material layer using a supercritical fluid will be described. FIGS. 6 and 7 are cross-sectional views illustrating a material layer forming process using a supercritical fluid, according to example embodiments.

Referring to FIG. 6, a supercritical fluid, in which precursors are melted, may flow over the substrate 42 on which a material layer is to be formed, and some of the precursors may be chemically bonded to a surface of the substrate 42. That is, some of the precursors melted in the supercritical fluid may be chemically adsorbed to the surface of the substrate 42. Reference numerals 60 and 62 refer to chemically adsorbed precursors. When the surface of the substrate 42 is covered with the chemically adsorbed precursors 60 and 62, some of the precursors melted in the supercritical fluid may be physically adsorbed to the chemically adsorbed precursors 60 and 62. Reference numeral 64 refers to a physically adsorbed precursor. The physically adsorbed precursor 64 may have a weaker bonding property than the chemically adsorbed precursors 60 and 62 on the surface of the substrate 42. Accordingly, the physically adsorbed precursor 64 may be detached from the chemically adsorbed precursors 60 and 62 in the continuous flow of the supercritical fluid. As a result, only the chemically adsorbed precursors 60 and 62 may remain on the surface of the substrate 42 as illustrated in FIG. 7. The substrate 42 and the chemically adsorbed precursors 60 and 62 on the surface of the substrate 42 function as a new substrate and the processes of FIGS. 6 and 7 are repeated. Thus, in the repeated processes, the precursors may be bonded to the substrate or to the previously chemically adsorbed precursors only by chemical adsorption. Accordingly, the repeated processes are not influenced by process variables, e.g., pressure or temperature.

Consequently, the precursors melted in the supercritical fluid may be sequentially chemically adsorbed to the substrate 42 to form a material layer. The material layer does not include the physically adsorbed precursors. Thus, physically adsorbed precursors do not exist on the surface of a structure having a high aspect ratio, and only chemically adsorbed precursors having a stronger bonding property than physically adsorbed precursors may be deposited. Thus, a material layer may be uniformly formed on the entire surface of the structure having a high aspect ratio. The supercritical fluid may have improved dissolving properties compared with gas, and thus, a material layer may be formed uniformly even in deep portions of the structure having a high aspect ratio.

After the precursor is chemically adsorbed during the material layer formation process, and before a next precursor is chemically adsorbed, a ligand of the previously chemically adsorbed precursor may be removed through the reactant material. This process is also repeated in the same manner after the subsequent chemical adsorption. The method of forming a material layer using a supercritical fluid may be applied in a similar manner to an atomic layer deposition (ALD) method.

FIG. 8 is a time chart in a material layer formation method using a supercritical fluid. The material layer formation method may be performed using the material layer forming apparatus 130 of FIG. 2. For example, as illustrated in FIG. 8, a supercritical fluid, in which a precursor is melted, may be supplied for a first time T1 to the material layer forming apparatus 130 in which the substrate 42 is loaded. Only a pure supercritical fluid which does not contain a precursor and a reactant material may be supplied to the material layer forming apparatus 130 for a second time T2. Thus, the physically adsorbed precursors may be removed from the substrate 42 during the second time T2.

A supercritical fluid, in which a reactant material is melted, may be supplied to the material layer forming apparatus 130 for a third time T3. Thus, the ligand may be removed from the precursor that is chemically adsorbed to the surface of the substrate 42 during the third time T3. A pure supercritical fluid which does not contain a precursor and a reactant material may be supplied to the material layer forming apparatus 130 for a fourth time T4. The processes performed during the first through fourth times T1 through T4 are repeated until a material layer having a desired thickness is formed. The first through fourth times T1 through T4 may be identical to one another or different from one another. Before supplying the supercritical fluid in which a precursor is melted during the first time T1, a pure supercritical fluid may be supplied to clean the surface of the substrate 42 or the inside of the material layer forming apparatus 130.

While example embodiments have been particularly shown and described in detail, example embodiments should be considered in descriptive sense only and not for purposes of limitation. For example, it will be understood by those skilled in the art that a shower head type depositing apparatus or a conventional depositing apparatus may be modified and used in depositing a material layer using a supercritical fluid. Also, a supercritical fluid may be used in depositing a material layer not only in fine and complicated structures but also in simpler structures. Also, the method of forming a material layer using a supercritical fluid may be applied in other fields where the ALD method may be used. Therefore, the scope of example embodiments is defined not by the detailed description of the embodiments but by the appended claims.

It should be understood that example embodiments described therein should be considered in a descriptive sense only and not for purposes of limitation. Descriptions of features or aspects within each embodiment should typically be considered as available for other similar features or aspects in other example embodiments.

What is claimed is:

1. A material layer forming system comprising:
a high pressure pump supplying a supercritical fluid to a precursor storage container, the precursor storage container supplying a precursor and the supercritical fluid to a material layer forming apparatus; and
a reactant material storage container supplying a reactant material to the material layer forming apparatus,
wherein the precursor and the reactant material react with each other in the material layer forming apparatus in order to form a material layer, and
the internal pressure of the precursor storage container, the reactant material storage container, and the material layer forming apparatus is maintained higher than about 1 atm.

2. The material layer forming system of claim 1, further comprising:
a pressure gauge adjusting the pressure of the material layer forming apparatus.

3. The material layer forming system of claim 1, wherein the precursor of the precursor storage container is supplied to the material layer forming apparatus using the supercritical fluid.

4. The material layer forming system of claim 1, wherein the supercritical fluid includes CO₂, and the internal pressure of the precursor storage container, the reactant material storage container, and the material layer forming apparatus is about 70 atm to about 200 atm.

5. The material layer forming system of claim 4, wherein the internal temperature of the precursor storage container, the reactant material storage container, and the material layer forming apparatus is higher than about 400 K and lower than about 700 K.

6. The material layer forming system of claim 1, wherein the material layer forming apparatus further comprises:
a susceptor including a substrate loaded thereon;
an upper board facing a surface of the susceptor including the substrate, the upper board being separate from the surface of the susceptor;
an inlet on a side of the material layer forming apparatus between the susceptor and the upper board, wherein the supercritical fluid including the precursor and the reactant material flow into the material layer forming apparatus through the inlet; and
an outlet on the other side of the material layer forming apparatus between the susceptor and the upper board, the outlet configured to discharge the supercritical fluid from the material layer forming apparatus.

7. A material layer forming apparatus comprising:
a susceptor including a substrate loaded thereon;
an upper board facing a surface of the susceptor including the substrate, the upper board being separate from the surface of the susceptor;
an inlet on a side of the material layer forming apparatus between the susceptor and the upper board, wherein the supercritical fluid including the precursor and the reactant material flow into the material layer forming apparatus through the inlet; and
an outlet on the other side of the material layer forming apparatus between the susceptor and the upper board, the outlet configured to discharge the supercritical fluid from the material layer forming apparatus,
wherein the internal pressure of the material layer forming apparatus is maintained to be higher than about 1 atm, and the supercritical fluid is supplied between the substrate and the upper board through the inlet.

8. The material layer forming apparatus of claim 7, wherein the inlet includes separate portions for supplying the reactant material and the supercritical fluid.

9. The material layer forming apparatus of claim 7, wherein the supercritical fluid includes CO₂, and the internal pressure of the material layer forming apparatus is about 70 atm to about 200 atm.

10. The material layer forming apparatus of claim 9, wherein the internal temperature of the material layer forming apparatus is higher than about 400 K and lower than about 700 K.

11. A method of forming a material layer comprising:
loading a substrate on a susceptor;
supplying a precursor to the substrate; and
supplying a reactant material to the substrate,
wherein the precursor is melted in a supercritical fluid before being supplied to the substrate.

12. The method of claim 11, wherein the reactant material is melted in the supercritical fluid before being supplied to the substrate.

13. The method of claim 11, wherein the precursor and the reactant material are supplied through different inlets.

14. The method of claim 11, wherein the material layer is formed at a pressure higher than about 1 atm.

15. The method of claim 11, wherein the material layer is formed at a temperature that is higher than about 400 K and lower than about 700 K.

16. The method of claim 12, wherein the precursor and the reactant material are supplied to the substrate at different times, further comprising:
supplying a pure supercritical fluid not containing the precursor and the reactant material to the substrate at a time between supplying the precursor and the reactant material.

17. The method of claim 16, wherein the pure supercritical fluid is supplied after supplying the reactant material and before supplying the precursor.

18. The method of claim 11, wherein the precursor and the reactant material are supplied in a parallel direction to the surface of the substrate where the material layer is formed.

19. The method of claim 11, wherein the precursor and the reactant material are continually supplied until the material layer is completely formed.

20. The method of claim 14, wherein the material layer is formed at a temperature that is higher than about 400 K and lower than about 700K.
